(19) United States
(12) Patent Application Publication
(10) Pub. No.: US 2006/0165873 A1
(43) Pub. Date: Jul. 27, 2006

(54) Plasma detection and associated systems and methods for controlling microfeature workpiece deposition processes

(75) Inventors: Neal R. Rueger, Boise, ID (US); Sanket Sant, Plano, TX (US)

Correspondence Address: PERKINS COIE LLP;PATENT-SEA, PO BOX 1247, SEATTLE, WA, 98111-1247, US

(73) Assignee: Micron Technology, Inc., Boise, ID (US)

(21) Appl. No.: 11/043,629

(22) Filed: Jan. 25, 2005

(51) Int. Cl. C23C 16/52; H01L 21/306; H05H 1/24; B05C 11/00; C23C 16/00

(52) U.S. Cl. 427/8; 427/569; 118/697; 156/345.24; 118/723 R; 118/715; 118/663

(57) ABSTRACT

Systems and methods for detecting plasmas and/or controlling microfeature workpiece deposition processes are disclosed. A method in accordance with one embodiment includes placing a microfeature workpiece in a plasma chamber, detecting a plasma in the plasma chamber while the microfeature workpiece is in the plasma chamber, and controlling processing of the microfeature workpiece in the plasma chamber based at least in part on the detection of the plasma. A controller in accordance with another embodiment of the invention can be configured to receive an indication of plasma initiation, track an exposure time based on the indication of plasma initiation, and compare the exposure time to a target value. If the exposure time meets or exceeds the target value, the controller can direct the plasma to be extinguished. If an indication that the plasma has been extinguished is received prior to the target exposure time being met, the controller can halt tracking the exposure time, await an indication of plasma re-initiation, and restart tracking the exposure time when the indication of plasma re-initiation is received.

### TECHNICAL FIELD

The present invention relates to plasma detection and associated systems and methods for controlling microfeature workpiece deposition processes.

### BACKGROUND

Thin film deposition techniques are widely used to build interconnects, plugs, gates, capacitors, transistors and other microfeatures when manufacturing microelectronic devices. Thin film deposition techniques are continually improved to meet the ever-increasing demands of the industry because the microfeature sizes are constantly decreasing and the number of microfeature layers is constantly increasing. As a result, the density of microfeatures and the aspect ratios of depressions (e.g., the ratio of the depth to the size of the opening) are increasing. Thin film deposition techniques have accordingly been developed to produce highly uniform conformal layers that cover the sidewalls, bottoms, and corners in deep depressions that have very small openings.

One widely used thin film deposition technique is chemical vapor deposition (CVD). In a CVD system, one or more reactive precursors are mixed in a gas or vapor state and then the precursor mixture is presented to the surface of the workpiece. The surface of the workpiece catalyzes a reaction between the precursors to form a solid, thin film at the workpiece surface. A common way to catalyze the reaction at the surface of the workpiece is to heat the workpiece to a temperature that causes the reaction. CVD processes are routinely employed in many stages of manufacturing microelectronic components.

Atomic layer deposition (ALD) is another thin film deposition technique that is gaining prominence in manufacturing microfeatures on workpieces. FIGS. 1A and 1B schematically illustrate the basic operation of ALD processes. Referring to FIG. 1A, a layer of “A” gas molecules coats the surface of a workpiece W. The layer of A molecules is formed by exposing the workpiece W to a precursor gas containing A molecules and then purging the chamber with a purge gas to remove excess A molecules. This process can form a monolayer of A molecules on the surface of the workpiece W because the A molecules at the surface are held in place during the purge cycle by physical adsorption forces at moderate temperatures, or by chemisorption forces at higher temperatures. The layer of A molecules is then exposed to another precursor gas containing “B” molecules. The A molecules react with the B molecules to form an extremely thin layer of solid material C on the workpiece W. Such thin layers are referred to herein as nanolayers because they are typically less than 1 nm thick and usually less than 2 Å thick. For example, each cycle may form a layer having a thickness of approximately 0.5-1.0 Å. The chamber is then purged again with a purge gas to remove excess B molecules.

Another type of CVD process is plasma CVD in which energy is added to the gases inside the reaction chamber to form a plasma. U.S. Pat. No. 6,347,602 discloses several types of plasma CVD reactors. FIG. 2 schematically illustrates a conventional plasma processing system that includes a processing vessel 210 and a microwave transmitting window 223. The plasma processing system further includes a microwave generator 211 having a rectangular wave guide 212 and a disk-shaped antenna 213. The microwaves radiated by the antenna 213 propagate through the window 223 and into the processing vessel 210 to produce a plasma by electron cyclotron resonance. The plasma causes a desired material to be coated onto a workpiece W. Suitable plasma generators and associated plasma detection units (which detect the presence of a plasma) are available from MKS Instruments Inc. of Wilmington, Mass. under the trade name ASTEX®AX7610.

Although plasma CVD and ALD processes are useful for several applications, such as gate hardening, they are at times difficult to use for depositing conductive materials onto the wafer. For example, when the precursors are introduced into the chamber to create a metal layer, a secondary deposit of the metal accumulates on the interior surface of the window 223. This secondary deposit of metal builds up on the window 223 as successive microfeature workpieces are processed. One problem is that the secondary deposit of metal has a low transmissivity to the microwave energy radiating from the antenna 213. After a period of time, the secondary deposit of metal can restrict and ultimately block the microwave energy from propagating through the window 223 and into the processing vessel 210. As a result, the energy transmitted through the window 223 may not be sufficient to “strike” or ignite the plasma in the vessel 210. However, a predictable, repeatable deposition process relies on exposing successive workpieces to the plasma for consistently uniform periods of time. If the plasma is not struck consistently, the layers deposited on successive workpieces will not have consistent properties (e.g., layer thicknesses). This in turn may cause defects in the components made from the workpieces.

### BRIEF DESCRIPTION OF THE DRAWINGS

FIGS. 1A and 1B are schematic cross-sectional views of stages in ALD processing in accordance with the prior art.

FIG. 2 is a schematic cross-sectional view of a plasma vapor deposition system in accordance with the prior art.

FIG. 3 is a schematic cross-sectional view of a plasma vapor deposition system configured in accordance with an embodiment of the invention.

FIGS. 4A-4B illustrate detectors for detecting a plasma in accordance with embodiments of the invention.

FIG. 5 is a flow diagram illustrating a process for detecting plasmas in plasma chambers in accordance with an embodiment of the invention.

FIG. 6 is a flow diagram illustrating a process for controlling exposure time in a plasma chamber, in accordance with an embodiment of the invention.

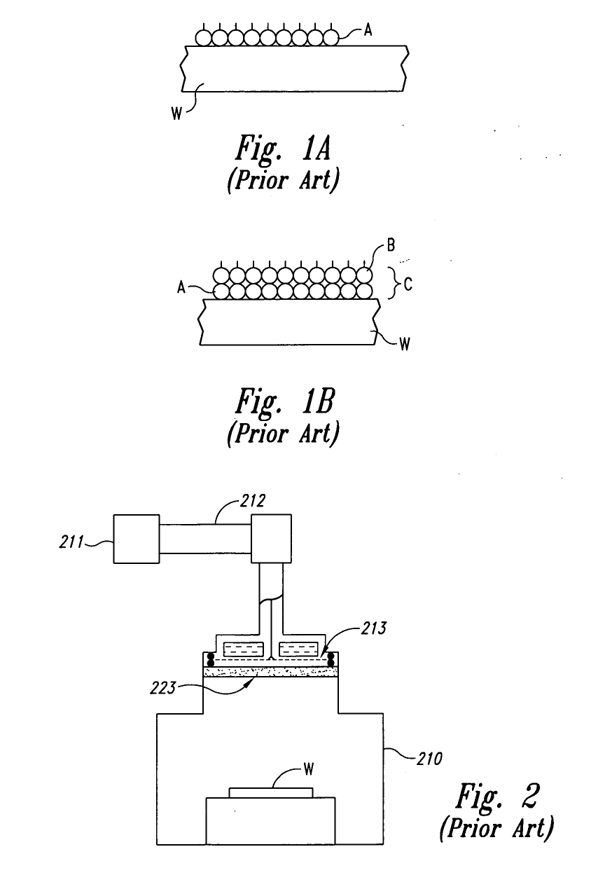

### DETAILED DESCRIPTION

A. Overview

Various embodiments of the present invention provide workpiece processing systems and methods for depositing materials onto microfeature workpieces. Many specific details of the invention are described below with reference to systems for depositing metals or other conductive materials onto microfeature workpieces, but the invention is also applicable to depositing other materials (e.g., dielectrics that have a low transmissivity to the plasma energy). The term “microfeature workpiece” is used throughout to include substrates upon which and/or in which microelectronic devices, micromechanical devices, data storage elements, read-write components, and other features are fabricated. For example, microfeature workpieces can be semiconductor wafers (e.g., silicon or gallium arsenide wafers), glass substrates, insulative substrates, and many other types of materials. The microfeature workpieces typically have submicron features with dimensions of a few nanometers or greater. Furthermore, the term “gas” is used throughout to include any form of matter that has no fixed shape and will conform in volume to the space available, which specifically includes vapors (i.e., a gas having a temperature less than the critical temperature so that it may be liquefied or solidified by compression at a constant temperature).

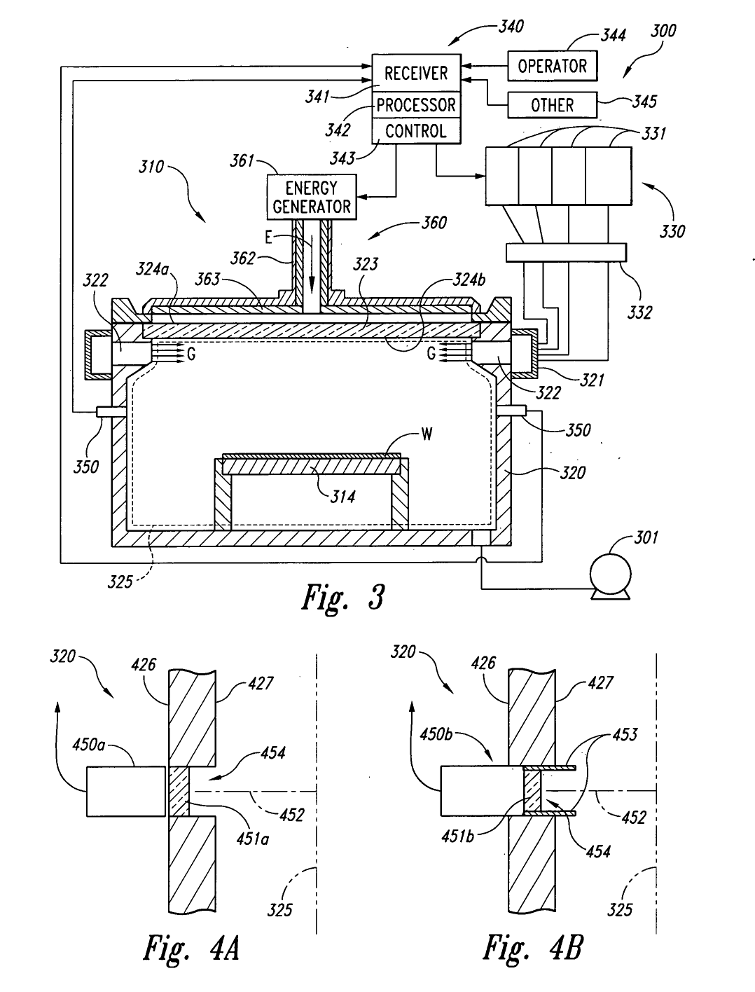

Several systems and methods in accordance with embodiments of the invention are set forth in FIGS. 3-6 and the following text to provide a thorough understanding of particular embodiments of the invention. A person skilled in the art, however, will understand that the invention may have additional embodiments, or that the invention may be practiced without several of the details of the embodiments shown in FIGS. 3-6.

Many embodiments of the invention described below may take the form of computer-executable instructions, including routines executed by a programmable computer or other controller. Those skilled in the relevant art will appreciate that the invention can be practiced on computer/controller systems other than those shown and described below. The invention can be embodied in a special-purpose computer, controller, or data processor that is specifically programmed, configured or constructed to perform one or more of the computer-executable instructions described below. Accordingly, the terms “computer” and “controller” as generally used herein refer to any data processor. Information handled by these devices can be presented at any suitable display medium, including a CRT display or LCD.

One aspect of the invention is directed toward methods for depositing material on a microfeature workpiece. The method can include placing the microfeature workpiece in a plasma chamber and detecting a plasma in the plasma chamber while the microfeature workpiece is in the plasma chamber. The method can further include controlling processing of the microfeature workpiece in the plasma chamber based at least in part on the detection of the plasma. In particular embodiments, the method can further include detecting extinction of the plasma in the plasma chamber, and determining an amount of time during which the microfeature workpiece is exposed to the plasma based at least in part on the detected initiation of the plasma and the detected extinction of the plasma.

In another aspect, the method can include automatically detecting a plasma in a plasma chamber, and exposing a target (e.g., a microfeature workpiece) to the plasma. The method can further include automatically controlling a time during which the target is exposed to the plasma, based at least in part on the detection of the plasma.

In yet a further aspect, the method can include receiving an indication of plasma initiation and tracking an exposure time based on the indication of plasma initiation. The method can further include comparing the exposure time to a target value for exposure time. If the exposure time meets or exceeds the target value, the method can include directing the plasma to be extinguished. If an indication that the plasma has been extinguished is received prior to the exposure time meeting or exceeding the target value, then the method can include halting the exposure time tracking, awaiting an indication of plasma re-initiation, and restarting tracking the exposure time when the indication of plasma re-initiation is received.

Other aspects of the invention are directed toward systems or apparatuses for applying material to a microfeature workpiece. One such apparatus includes a plasma chamber coupleable to a source of gas. A support can be positioned within the plasma chamber and can be configured to carry a microfeature workpiece. An energy source can be positioned at least proximate to the plasma chamber to impart energy to atoms within the plasma chamber. The apparatus can further include a detector positioned to detect the presence of a plasma within the plasma chamber, and a controller operatively coupled to the energy source and the detector to control operation of the energy source based at least in part on a signal received from the detector. In particular embodiments, the detector can include a photosensitive diode, and/or can be configured to detect the presence of ions in the plasma chamber. The detector can include a window positioned to be in a direct line of sight with an interior region of the plasma chamber, and can further include a shield positioned proximate to the window to at least restrict deposition of material on the window.

B. Embodiments of Plasma Vapor Deposition Systems

FIG. 3 is a schematic cross-sectional view of a plasma vapor deposition system 300 for depositing a material onto a microfeature workpiece or other substrate. The deposition system 300 can perform CVD, ALD, and/or pseudo ALD processes. In this embodiment, the deposition system 300 includes a reactor 310 having a reactor chamber 320, a gas supply 330 configured to produce and/or contain gases, and an energy system 360. A controller 340 contains computer-operable instructions that can control the energy system 360, the gas supply 330, and/or other aspects of the deposition system 300. By controlling the energy system 360, the controller 340 can automatically track and control process parameters, including the amount of time the microfeature workpiece W is exposed to a plasma. Accordingly, the system 300 can produce workpieces W with more uniformly applied material layers.

The deposition system 300 is suitable for plasma vapor deposition of several different types of materials, and it has particular utility for depositing conductive materials using microwave energy to generate a plasma in the reactor 310. To date, it has been difficult to deposit certain metals or other conductive materials without using a plasma enhanced system because one or more precursors may need additional energy to cause the reaction that forms the thin conductive film. Although prior art plasma vapor deposition systems provide the additional energy to cause the necessary reaction, they also secondarily deposit the conductive material onto the interior surface of the reactor 310. The secondary deposition of the conductive material on the interior surfaces of the reaction chamber 320 impedes the microwave energy from entering the reaction chamber and forming the plasma. Accordingly, the plasma may not “strike” or ignite in a consistent manner. The prior art plasma vapor deposition chambers are thus unsuitable for depositing many metals. As explained in more detail below, embodiments of the deposition system 300 resolve this problem by tracking the amount of time the workpiece W is exposed to an ignited plasma. Once the target time has been reached, the system 300 can automatically halt the deposition process (e.g., extinguish the plasma). If the plasma extinguishes prematurely for any reason, the system 300 can re-initiate the plasma and continue exposing the workpiece W to the plasma until a target exposure time has elapsed.

Referring to the embodiment of the deposition system 300 shown in FIG. 3, the reaction chamber 320 includes a gas distributor or manifold 321 coupled to the gas supply 330, a workpiece holder 314 for holding a workpiece W, and a main plasma zone 325 where a plasma can be generated. The gas manifold 321 can be an annular antechamber having a plurality of ports 322 for injecting or flowing the gases G into the reaction chamber 320. More specifically, the gas manifold 321 can have a plurality of different conduits so that individual gases are delivered into the main plasma zone 325 through one or more dedicated ports 322. Gases are evacuated from the reaction chamber 320 with a vacuum pump 301 or other suitable device.

The reactor 310 can further include a window 323 having a first surface 324a and a second surface 324b. The window 323 can be a plate or pane of material through which energy propagates into the reaction chamber 320 to generate a plasma in the main plasma zone 325. The window 323 accordingly has a high transmissivity to the energy that generates the plasma. For example, when microwave energy is used to generate the plasma, the window 323 can be a quartz plate or other material that readily transmits microwaves.

The energy system 360 can include a generator 361, an energy guide 362 coupled to the generator 361, and an antenna 363 or other type of transmitter coupled to the energy guide 362. The generator 361 can be a microwave generator. For example, the generator 361 can produce microwave energy at 2.45 GHz or another frequency suitable for producing a plasma in the main plasma zone 325. The generator 361 generates energy E that propagates through the energy guide 362 to the antenna 363, and the antenna 363 transmits the energy E through the window 323 to the main plasma zone 325. Additional energy can optionally be provided directly to the workpiece W via a heater positioned in the workpiece holder or support 314. The workpiece holder 314 can be rotated to uniformly expose the workpiece W to the plasma.

Referring still to FIG. 3, the gas supply 330 can include multiple gas supply vessels 331 coupled to a valve system 332. Individual gas supply vessels 331 contain or produce individual process gases (e.g., precursor gases, purge gases, and/or maintenance gases), as disclosed in copending U.S. application Ser. No. 10/683,606, filed Oct. 9, 2003 and incorporated herein by reference. The gas supply 330 is not limited to having three vessels 331, but rather it can have any number of individual vessels so as to provide the desired precursors and/or purge gases to the gas manifold 321. As such, the gas supply 330 can include more or fewer precursor gases and/or purge gases than are shown in FIG. 3. These gases are withdrawn from the reaction chamber 320 with a vacuum source 301.

The system 300 can also include one or more detectors 350 (two are shown in FIG. 3) that are configured to identify when the plasma within the reaction chamber 320 has been struck, ignited, or otherwise initiated. Multiple detectors 350 can provide a level of redundancy (in case one detector 350 fails) and/or can be useful in cases where the plasma is or is expected to be non-uniform. The detectors 350 can use any of several detection techniques. One such technique includes detecting the emission of photons that results when a plasma is struck. Another technique includes detecting ions that are present in the reaction chamber 320 when the plasma has been initiated. Still a further technique includes using mass spectrometry to determine when gaseous species associated with an initiated plasma are present in the reaction chamber 320.

Regardless of which detection technique is used, the detector or detectors 350 can transmit signals to the controller 340 identifying when a plasma is present. The absence of such a signal (or, alternatively, the presence of a separate signal) can indicate that the plasma is extinguished. The controller 340 can then influence the process taking place in the reaction chamber 320 based upon the information received from the detectors 350. The controller 340 can accordingly include a receiver portion 341 that (a) receives signals transmitted by the detectors 350 and (b) optionally receives signals from an operator 344 or from other sources 345. A processor portion 342 can process the signals received by the receiver portion 341, and a control portion or director 343 can control the operation of the energy generator 361 and/or the gas supply 330, based at least in part upon the signals received from the detectors 350. For example, the processor portion 342 can include a timer that tracks the amount of time the plasma in the reaction chamber 320 is struck. The elapsed time can be compared with a target value (provided by the operator 344 or another source 345) and, after the target time has elapsed, the control portion 343 can extinguish the plasma by interrupting power provided by the energy generator 361. If the plasma produced in the reaction chamber 320 is produced only intermittently, the processor portion 342 can compile segments of elapsed time, and the control portion 343 can extinguish the plasma only after the entire target elapsed time has passed. Further details of the operation of the controller 340 are provided below with reference to FIGS. 5 and 6, and FIGS. 4A and 4B illustrate plasma detectors configured in accordance with different embodiments of the invention.

Beginning with FIG. 4A, a plasma detector 450a can be positioned external to a chamber wall 426 of the reaction chamber 320. The chamber wall 426 can include an aperture into which a window 451a is placed. The window 451a can be made from quartz or other materials that are transmissive to the radiation emitted by the plasma within the chamber 320. In a particular aspect of this embodiment, the window 451a is positioned so as to have a direct line of sight 452 to the main plasma zone 325. Accordingly, the detector 450a can readily detect the initiation of the plasma in the main plasma zone 325 by receiving photons that travel along the line the sight 452. In a further aspect of this embodiment, the window 451a can be offset from an inner surface 427 of the chamber wall 426, leaving a recess 454 located between the window 451a and the inner surface 427. An advantage of this construction is that it can reduce the likelihood that constituents of the plasma will be deposited on the window 451a.

In one aspect of this embodiment, the detector 450a can include a photodetector, for example, a photodiode. In other embodiments, the detector 450a can include other devices configured to detect photon emissions from the plasma. The photon emissions can have a wavelength in the range of from about 300 nanometers to about 900 nanometers, depending upon the constituents of the plasma. In other embodiments, the emissions from the plasma can have other wavelengths, and accordingly, the detector can be tailored to detect emissions at such wave lengths.

FIG. 4B illustrates a detector 450b that is integrated with the chamber wall 426. Accordingly, the detector 450b itself can include a window 451b that is aligned with the line of sight 452 extending between the detector 450b and the main plasma zone 325. In addition to being recessed from the inner surface 427 of the chamber wall 426, the detector 450b can include an optional shield 453 that encircles the window 451b and projects inwardly from the inner surface 427 to further protect the window 451b from incidental deposition by constituents of the plasma.

C. Embodiments of Methods for Controlling Plasma Vapor Deposition

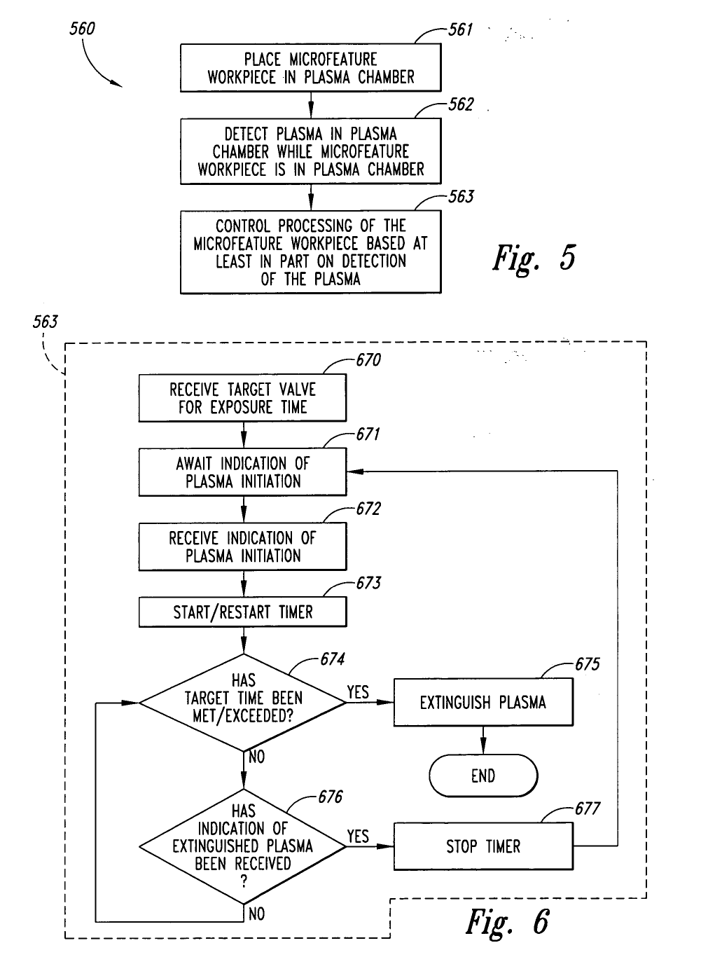

FIG. 5 illustrates a process 560 for depositing material on a microfeature workpiece in accordance with an embodiment of the invention. In process portion 561, the microfeature workpiece is placed in a plasma chamber. In process portion 562, a plasma is detected in the plasma chamber while the microfeature workpiece is in the plasma chamber. In process portion 563, at least one aspect of the process carried out on the microfeature workpiece (e.g., a deposition process) can be controlled, based at least in part on the detection of the plasma.

FIG. 6 illustrates one embodiment of a process portion 563 for controlling the processing of the microfeature workpiece. In this embodiment, controlling processing of the microfeature workpiece can include receiving a target value for a time during which the microfeature workpiece (or other substrate) is to be exposed to an initiated plasma (process portion 670). The process can then include awaiting an indication of plasma initiation (process portion 671). In process portion 672, the indication of plasma initiation is received, for example, via the detectors 350 described above with reference to FIG. 3. In process portion 673, the process can include starting (or restarting) a timer, based upon the indication of plasma initiation received in process portion 672. In process portion 674, the process includes determining whether the target time has been met or exceeded. In other words, the process can include comparing the target value received in process portion 670, with the elapsed time during which the workpiece or other substrate has been exposed to an initiated plasma. If the target time has been met or exceeded, the process can include extinguishing the plasma (process portion 675) and the process can end. The process can be re-initiated when an additional layer is to be deposited on the present workpiece (or other substrate), or when new material is to be applied to another workpiece.

If the target time has not been met or exceeded, the process can include checking whether an indication of an extinguished plasma has been received (process portion 676). If the plasma has been extinguished, the process can include stopping the timer (process portion 677) and returning to process portion 671 to await an indication of the next plasma initiation. In other words, the process can include pausing the timer if the plasma has been extinguished before the target time has elapsed. The timer can be restarted once the plasma has been re-initiated.

The following particular example (provided with reference to FIG. 3) highlights a process in which the foregoing techniques may be suitable. In this representative process, titanium is supplied in an ALD process to a silicon workpiece W. Initially, TiCl₄ is introduced into the reaction chamber 320. TiCl₃ bonds to the silicon and becomes inert, and the remaining Cl ion is removed from the chamber via the vacuum pump 301. To remove the remaining Cl atoms from the silicon (leaving a pure titanium layer), hydrogen is introduced into the reaction chamber 320. The hydrogen is ionized to produce a plasma, which breaks the bonds between the titanium and chlorine atoms at the workpiece surface, and allows the hydrogen atoms to bond to the chlorine atoms, forming hydrogen chloride. The hydrogen chloride is then removed from the chamber, leaving a pure titanium layer on the workpiece surface. The foregoing process can be completed in 4-5 seconds and can be repeated as necessary to build up a titanium layer having the desired thickness.

If the foregoing process is allowed to continue for longer than a targeted exposure time, the surface of the wafer may become sputtered (e.g., the titanium atoms may be forced from the surface) resulting in a non-uniform surface topography. Conversely, if the process is not allowed to continue for the entire target time (which may happen if the plasma extinguishes before the target time has elapsed), then not all the chlorine atoms will be removed from the TiCl₃ initially deposited on the microfeature workpiece. Because titanium subsequently introduced into the chamber 320 will only bond to exposed titanium at the surface of the microfeature workpiece W, any remaining chlorine atoms may interfere with this process. This can in turn reduce the uniformity of the overall titanium layer, and/or can result in chlorine atoms buried in the titanium layer. By (a) automatically tracking the exposure time and extinguishing the plasma process when the exposure time has been met, and/or (b) automatically accounting for periods during which the plasma may be prematurely extinguished, the foregoing systems and methods can avoid both over- and under-exposing the workpiece to the plasma. An advantage of these features is that they can allow each microfeature workpiece to be processed in a uniform manner, and can accordingly provide uniformity over multiple processed microfeature workpieces.

From the foregoing, it will be appreciated that specific embodiments of the invention have been described herein for purposes of illustration, but that various modifications may be made without deviating from the spirit and scope of the invention. For example, aspects of the invention were described above in the context of processes completed on microfeature workpieces. In other embodiments, these processes may be completed on other substrates. In still further embodiments, at least portions of the foregoing methods may be used in processes other than deposition processes, whether on microfeature workpieces, other substrates, or in the absence of any substrates. Aspects of the invention described in the context of particular embodiments may be combined or eliminated in other embodiments. For example, the shield described in the context of an integrated detector may also be used with a detector that is not integrated with the chamber wall. Although advantages associated with certain embodiments of the invention have been described in the context of those embodiments, other embodiments may also exhibit such advantages. Additionally, none of the foregoing embodiments need necessarily exhibit such advantages to fall within the scope of the invention. Accordingly, the invention is not limited except as by the appended claims.

I/We claim:

1. A method for depositing material on a microfeature workpiece, comprising:
placing the microfeature workpiece in a plasma chamber;
detecting a plasma in the plasma chamber while the microfeature workpiece is in the plasma chamber; and
controlling processing of the microfeature workpiece in the plasma chamber based at least in part on the detection of the plasma.

2. The method of claim 1 wherein detecting a plasma includes detecting initiation of a plasma.

3. The method of claim 1 wherein detecting a plasma includes detecting a radiative emission from atoms within the plasma chamber.

4. The method of claim 1 wherein detecting a plasma includes detecting an optical emission from atoms within the plasma chamber.

5. The method of claim 1 wherein detecting a plasma includes detecting a concentration of ions in the plasma chamber.

6. The method of claim 1, further comprising:
introducing a gas into the plasma chamber;
directing electromagnetic energy into the plasma chamber; and
striking the plasma in the plasma chamber by ionizing at least a portion of the gas in the chamber.

7. The method of claim 1 wherein detecting a plasma includes detecting a first initiation of the plasma, and wherein the method further comprises:
detecting a first extinction of the plasma in the plasma chamber while the microfeature workpiece is in the plasma chamber;
determining an amount of time during which the microfeature workpiece is exposed to the plasma based at least in part on the detected first initiation of the plasma and the detected first extinction of the plasma;
detecting a second initiation of the plasma in the plasma chamber while the microfeature workpiece is in the plasma chamber;
detecting a second extinction of the plasma in the plasma chamber while the microfeature workpiece is in the plasma chamber; and
updating the amount of time during which the microfeature workpiece is exposed to the plasma based at least in part on the detected second initiation of the plasma and the detected second extinction of the plasma.

8. The method of claim 1 wherein detecting a plasma includes detecting initiation of a plasma, and wherein the method further comprises:
detecting extinction of the plasma in the plasma chamber while the microfeature workpiece is in the plasma chamber; and
determining an amount of time during which the microfeature workpiece is exposed to the plasma based at least in part on the detected initiation of the plasma and the detected extinction of the plasma.

9. The method of claim 1 wherein detecting a plasma includes detecting initiation of the plasma, based on a first signal from a photosensitive diode, and wherein the method further comprises:
(a) detecting extinction of the plasma in the plasma chamber while the microfeature workpiece is in the plasma chamber, based on a second signal received from the photosensitive diode; and
determining an amount of time during which the microfeature workpiece is exposed to the plasma based at least in part on the detected initiation of the plasma and the detected extinction of the plasma; or
(b) extinguishing the plasma after a threshold period of time has elapsed; or
(c) both (a) and (b).

10. The method of claim 1, further comprising detecting extinction of the plasma in the plasma chamber.

11. The method of claim 1 wherein controlling a process includes:
receiving an indication of a target plasma exposure time for the microfeature workpiece; and
extinguishing the plasma after the target period of time has elapsed.

12. The method of claim 1 wherein controlling a process includes:
determining an amount of time during which the microfeature workpiece is exposed to the plasma based at least in part on the detection of the plasma;
comparing the amount of time to a target plasma exposure time for the microfeature workpiece; and
extinguishing the plasma in response to the amount of time meeting or exceeding the target plasma exposure time.

13. The method of claim 1, further comprising rotating the microfeature workpiece while the microfeature workpiece is exposed to the plasma.

14. The method of claim 1 wherein detecting a plasma in the plasma chamber includes detecting the plasma via at least one of a plurality of detectors positioned at least proximate to the plasma chamber.

15. A method for controlling a plasma process, comprising:
automatically detecting a plasma in a plasma chamber;
exposing a target to the plasma; and
automatically controlling a time during which the target is exposed to the plasma based at least in part on the detection of the plasma.

16. The method of claim 15 wherein exposing a target includes exposing a microfeature workpiece to deposit material on the microfeature workpiece.

17. The method of claim 15 wherein detecting a plasma includes detecting initiation of a plasma.

18. The method of claim 15 wherein detecting a plasma includes detecting a radiative emission from atoms within the plasma chamber.

19. The method of claim 15 wherein detecting a plasma includes detecting a first initiation of the plasma, and wherein the method further comprises:
detecting a first extinction of the plasma in the plasma chamber while the target is in the plasma chamber;
determining an amount of time during which the target is exposed to the plasma based at least in part on the detected first initiation of the plasma and the detected first extinction of the plasma;
detecting a second initiation of the plasma in the plasma chamber while the target is in the plasma chamber;
detecting a second extinction of the plasma in the plasma chamber while the target is in the plasma chamber; and
updating the amount of time during which the target is exposed to the plasma based at least in part on the detected second initiation of the plasma and the detected second extinction of the plasma.

20. The method of claim 15 wherein detecting a plasma includes detecting initiation of a plasma, and wherein the method further comprises:
detecting extinction of the plasma in the plasma chamber while the target is in the plasma chamber; and
determining an amount of time during which the target is exposed to the plasma based at least in part on the detected initiation of the plasma and the detected extinction of the plasma.

21. The method of claim 15, further comprising detecting extinction of the plasma in the plasma chamber.

22. The method of claim 15 wherein controlling a process includes:
receiving an indication of a pre-selected plasma exposure time for the target; and
extinguishing the plasma after the pre-selected period of time has elapsed.

23. The method of claim 15 wherein detecting a plasma in the plasma chamber includes detecting the plasma via at least one of a plurality of detectors positioned at least proximate to the plasma chamber.

24. A method for depositing material on a microfeature workpiece, comprising:
placing the microfeature workpiece in a plasma chamber;
reducing a pressure in the plasma chamber;
igniting constituents in the plasma chamber;
detecting ignition of constituents in the plasma chamber based on a first signal received from a photosensitive diode; and
(a) detecting extinction of the plasma in the plasma chamber while the microfeature workpiece is in the plasma chamber, based on a second signal received from the photosensitive diode; and
determining an amount of time during which the microfeature workpiece is exposed to the ignited plasma based at least in part on the detected initiation of the plasma and the detected extinction of the plasma; or
(b) extinguishing the ignited constituents after a threshold period of time has elapsed; or
(c) both (a) and (b).

25. The method of claim 24 wherein detecting ignition includes detecting a first initiation of the plasma, and wherein detecting extinction of the plasma includes detecting a first extinction of the plasma, and wherein the method further comprises:
detecting a second initiation of the plasma in the plasma chamber while the microfeature workpiece is in the plasma chamber;
detecting a second extinction of the plasma in the plasma chamber while the microfeature workpiece is in the plasma chamber; and
updating the amount of time during which the microfeature workpiece is exposed to the plasma based at least in part on the detected second initiation of the plasma and the detected second extinction of the plasma.

26. A method for controlling plasma exposure time, comprising:
receiving an indication of plasma initiation;
tracking an exposure time based at least in part on the indication of plasma initiation;
comparing the exposure time to a target value for exposure time;
if the exposure time meets or exceeds the target value, directing the plasma to be extinguished; and
if an indication that the plasma has been extinguished is received prior to the exposure time meeting or exceeding the target value, then
(a) halting tracking the exposure time;
(b) awaiting an indication of plasma re-initiation; and
(c) restarting tracking the exposure time when the indication of plasma re-initiation is received.

27. The method of claim 26 wherein tracking an exposure time includes tracking a time during which a microfeature workpiece is exposed to the plasma.

28. The method of claim 26 wherein receiving an indication of plasma initiation includes receiving an indication of plasma initiation from an optical detector.

29. The method of claim 26 wherein receiving an indication of plasma initiation includes receiving an indication of plasma initiation from a photosensitive diode.

30. A computer-readable medium for controlling operation of a plasma chamber, comprising:
a receiver portion configured to receive a signal corresponding to the presence of a plasma in a plasma chamber;
a timer portion configured to determine a period of time during which the plasma is present in the plasma chamber, based at least in part of the received signal; and
a control portion configured to direct a control signal that controls a power source used to initiate the plasma.

31. The computer-readable medium of claim 30 wherein the receiver portion is configured to receive a signal corresponding to the initiation of a plasma.

32. The computer-readable medium of claim 30 wherein the receiver portion is configured to receive a signal corresponding to a first initiation of a plasma while a target is present in the plasma chamber, and wherein:
the receiver portion is configured to receive a signal corresponding to a first extinction of the plasma in the plasma chamber;
the timer portion is configured to determine an amount of time during which the target is exposed to the plasma based at least in part on the detected first initiation of the plasma and the detected first extinction of the plasma;
the receiver portion is configured to receive a signal corresponding to a second initiation of the plasma in the plasma chamber while the target is in the plasma chamber;
the receiver portion is configured to receive a signal corresponding to a second extinction of the plasma in the plasma chamber while the target is in the plasma chamber; and
the timer portion is configured to update the amount of time during which the target is exposed to the plasma based at least in part on the detected second initiation of the plasma and the detected second extinction of the plasma.

33. The computer-readable medium of claim 30 wherein:
the receiver portion is configured to receive a first signal corresponding to an initiation of the plasma and a second signal corresponding to an extinction of the plasma in the plasma chamber while a target is in the plasma chamber; and
the timer portion is configured to determine an amount of time during which the target is exposed to the plasma based at least in part on the detected initiation of the plasma and the detected extinction of the plasma.

34. The computer-readable medium of claim 30 wherein the receiver portion is configured to receive a signal corresponding to extinction of the plasma in the plasma chamber.

35. The computer-readable medium of claim 30 wherein the control portion is configured to extinguish the plasma after a pre-selected period of time has elapsed.

36. An apparatus for applying material to a microfeature workpiece, comprising:
a plasma chamber coupleable to a source of gas;
a support positioned within the plasma chamber and configured to carry a microfeature workpiece;
an energy source positioned at least proximate to the plasma chamber to impart energy to atoms within the plasma chamber;
a detector positioned to detect the presence of a plasma within the plasma chamber; and
a controller operatively coupled to the energy source and the detector to control operation of the energy source based at least in part on a signal received from the detector.

37. The apparatus of claim 36 wherein the detector includes a photosensitive diode.

38. The apparatus of claim 36 wherein the detector is configured to detect a presence of ions in the plasma chamber.

39. The apparatus of claim 36 wherein the detector is configured to detect both the presence and absence of a plasma, and wherein the controller is configured to track an amount of time during which the plasma is ignited based at least in part on signals received from the detector.

40. The apparatus of claim 36 wherein the detector includes a photodetector having a window positioned to be in a direct line of sight with an interior region of the plasma chamber, and wherein the detector further includes a shield positioned proximate to the window to at least restrict deposition of material on the window.

41. The apparatus of claim 36 wherein the detector is one of a plurality of detectors positioned to detect the presence of a plasma within the plasma chamber.

42. The apparatus of claim 36 wherein the support is rotatable relative to the plasma chamber.

43. An apparatus for applying material to a microfeature workpiece, comprising:
a plasma chamber coupleable to a source of gas;
a support positioned within the plasma chamber and configured to carry a microfeature workpiece;
an energy source positioned at least proximate to the plasma chamber to impart energy to atoms within the plasma chamber;
a photodetector positioned to detect the presence of a plasma within the plasma chamber based on photon emissions from the plasma; and
a controller operatively coupled to the energy source and the detector to control operation of the energy source based at least in part on a signal received from the detector, the controller being configured to:
receive an indication of plasma initiation;
track an exposure time based on the indication of plasma initiation;
compare the exposure time to a target value for exposure time;
if the exposure time meets or exceeds the target value, direct the plasma to be extinguished; and
if an indication that the plasma has been extinguished is received prior to the exposure time meeting or exceeding the target value, then
(a) halt tracking the exposure time;
(b) await an indication of plasma re-initiation; and
(c) restart tracking the exposure time when the indication of plasma re-initiation is received.

44. The apparatus of claim 43 wherein the support is rotatable relative to the plasma chamber.

45. The apparatus of claim 43 wherein the photodetector is one of multiple photodetectors.

46. An apparatus for applying material to a microfeature workpiece, comprising:
a plasma chamber coupleable to a source of gas;
a support positioned within the plasma chamber and configured to carry a microfeature workpiece;
an energy source positioned at least proximate to the plasma chamber to impart energy to atoms within the plasma chamber;
detection means for detecting the presence of a plasma within the plasma chamber; and
control means operatively coupled to the energy source and the detector means to control operation of the energy source based at least in part on a signal received from the detection means.

47. The apparatus of claim 46 wherein the control means is configured to:
receive an indication of plasma initiation;
track an exposure time based on the indication of plasma initiation;
compare the exposure time to a target value for exposure time;
if the exposure time meets or exceeds the target value, direct the plasma to be extinguished; and
if an indication that the plasma has been extinguished is received prior to the exposure time meeting or exceeding the target value, then
(a) halt tracking the exposure time;
(b) await an indication of plasma re-initiation; and
(c) restart tracking the exposure time when the indication of plasma re-initiation is received.

48. The apparatus of claim 46 wherein the control means includes a computer-readable medium.

49. The apparatus of claim 46 wherein the detection means includes a photodetector.
